(19) United States
(12) Patent Application Publication
(10) Pub. No.: US 2005/0057380 A1
(43) Pub. Date: Mar. 17, 2005

(54) Apparatus for sampling a plurality of analog signals

(75) Inventor: Woon Na, Suwon-si (KR)

Correspondence Address: Steven M. Mills;MILLS & ONELLO LLP, Suite 605, Eleven Beacon Street, Boston, MA, 02108, US

(73) Assignee: Samsung Electronics Co., Ltd.

(21) Appl. No.: 10/876,959

(22) Filed: Jun. 25, 2004

(30) Foreign Application Priority Data
Sep. 16, 2003 (KR) 03-64143

(51) Int. Cl. H03M 1/00

(52) U.S. Cl. 341/123

(57) ABSTRACT

An analog-to-digital conversion apparatus includes a sampling clock generator and an analog-to-digital converter. The sampling clock generator receives a clock signal and generates a plurality of sampling clock signals in response to phase control signals. The analog-to-digital converter receives a plurality of analog signals, samples the received analog signals and outputs digital signals synchronized with the sampling clock signals outputted from the sampling clock generator. The sampling clock signals outputted from the sampling clock generator correspond to the analog signals respectively. Therefore, the analog-to-digital converter can sample the inputted analog image signal when the inputted analog image signal is in the stable state. Thus, the analog-to-digital converter can output the optimal digital signal.

### RELATED APPLICATION

This application claims priority to Korean patent application number 2003-64143, filed on Sep. 16, 2003, the contents of which are incorporated herein in their entirety by reference.

### BACKGROUND OF THE INVENTION

1. Field of the Invention

The present invention relates to an apparatus and method for sampling a plurality of analog signals and, more particularly, to an apparatus and method for sampling a plurality of analog signals in a display device such as a flat panel display.

2. Description of the Related Art

Electronic devices such as a computer, a monitor, a flat panel display, a wireless communication device and a paging device use a plurality of electrical signals. Theses electrical signals include a clock signal, a horizontal synchronization signal, a vertical synchronization signal and a digital wireless communication signal. The main trend in electronic devices is to use digital signals. As is well known, it is very advantageous that the electronic devices express an electrical signal as a digital signal. However, an analog signal is used even now so as to communicate with old media that receives information in only analog format. As a result, it is required to convert the analog electrical signal into a digital signal after communicating with the old media.

An analog-to-digital converter is used to sample an analog electrical signal at a predetermined interval and represent the sampled electrical signal as a digital signal. The analog-to-digital converter compares a voltage amplitude of an input signal with a plurality of reference voltages at a fixed time and outputs a digital signal. In contrast, a digital-to-analog converter converts an electrical signal represented digitally into an analog signal.

A computer graphic controller using frame buffer data converts a digital image signal into an analog signal through the digital-to-analog converter and supplies the analog signal as an output of the computer graphic interface. This output image signal is used to drive a display device. The image signal is connected to an interface of the display device through a cable. Transmission through a cable causes a noise signal and distorts an analog signal. For example, this distortion is caused by capacitance and inductance of cable media, and includes jitter of an output of the computer graphic interface. FIG. 1 illustrates an example of an analog signal received by a display device, which is transmitted from a computer graphic interface through a cable. As shown in FIG. 1, the received analog signal includes stable regions in which a constant level is maintained, and unstable regions characterized by pre-shoot, over-shoot, ringing or settling, synchronous noise and steep edges.

U.S. Pat. No. 6,473,131 discloses a device and a method for sampling an analog signal in stable regions when the received analog signal includes unstable regions and stable regions.

A plurality of analog image signals such as red (R)-, green (G)- and blue (B)-image signals may be delayed differently due to transmission media, and the stable regions of the R-, G- and B-image signals do not coincide with each other due to noise. When a plurality of the differently delayed analog signals with the different stable regions are sampled with sampling clock signals having the same phase, some analog signals may be sampled in the stable regions but the others may be sampled in the unstable regions. FIG. 2 illustrates an example of image signals sampled with the same sampling clock signal. Referring to FIG. 2, SP depicts a sampling point. Image signals RA and BA are sampled in stable data regions but an image signal GA is sampled in unstable regions.

As shown in FIG. 2, when a plurality of the differently delayed analog signals with different stable regions are sampled with sampling clock signals having the same phase, the stable region in which all the plurality of analog signals are sampled is smaller than each of the stable regions of the analog signals.

The display device should sample input signals in the stable regions so as to optimally display analog image signals inputted from the host. If a signal is sampled in the unstable region, deteriorated data and noise are displayed on a screen.

### SUMMARY OF THE INVENTION

Accordingly, the present invention is directed to an apparatus for sampling a plurality of analog signals that substantially obviates one or more problems due to limitations and disadvantages of the related art.

It is an feature of the present invention to provide an apparatus for sampling a plurality of analog signals, with considering different delays of the analog signals.

It is another feature of the present invention to provide an apparatus for sampling a plurality of analog signals when all the analog signals are in stable state.

It is another feature of the present invention to provide an analog-to-digital conversion apparatus for converting a plurality of analog signals into a plurality of digital signals, with considering different delays of the analog signals.

It is another feature of the present invention to provide an analog-to-digital conversion apparatus for converting a plurality of analog signals into a plurality of digital signals when all the analog signals are in stable regions.

It is another feature of the present invention to provide a display device provided with an analog-to-digital converter for converting a plurality of analog image signals into a plurality of digital image signals when all the analog image signals are in stable regions.

In an aspect of the present invention, there is provided a sampling apparatus including: a clock generator for receiving a clock signal and generating sampling clock signals; and a sampling circuit for receiving a plurality of analog signals and sampling the received analog signals synchronized with the sampling clock signals, wherein the clock generator generates the sampling clock signals to change sampling points for the plurality of analog signals.

In one embodiment, each of the analog signals corresponds to each of the sampling clock signals in a one-to-one manner.

The sampling circuit can include a plurality of sampling units corresponding to the plurality of analog signals, for sampling the corresponding analog signal synchronized with the corresponding sampling clock signal.

In this embodiment, the clock generator can generate the sampling clock signals in response to phase control signals corresponding to the analog signals.

In another aspect of the present invention, there is provided an analog-to-digital conversion apparatus including: a clock generator for receiving a clock signal and generating sampling clock signals; and an analog-to-digital converter for receiving a plurality of analog signals and converting the received analog signals into digital signals synchronized with the sampling clock signals, wherein the clock generator generates the sampling clock signals for the analog-to-digital converter to change sampling points for the plurality of analog signals.

In one embodiment, the clock generator generates the sampling clock signals for the analog-to-digital converter to convert the analog signals into the digital signals when all the plurality of analog signals are in stable regions.

The analog-to-digital converter can include a plurality of conversion units corresponding to the plurality of analog signals, for converting the corresponding analog signal into a digital signal synchronized with the corresponding sampling clock signal.

In this embodiment, the clock generator can generate the sampling clock signals in response to phase control signals corresponding to the analog signals.

The clock generator can include clock delay circuits corresponding to the analog signals, for delaying the clock signal for a predetermined time and generating the sampling clock signal.

In one embodiment, each of the clock delay circuits delays the clock signal for a time corresponding to the received phase control signal and generates the sampling clock signal.

In one embodiment, each of the clock delay circuits includes: a plurality of delayers connected in series, for receiving the synchronization signal; and a clock selector for outputting an output of a delayer corresponding to the received phase control signal among the delayers as a sampling clock signal.

In one embodiment, the clock generator includes: a plurality of delayers connected in series, for receiving the clock signal and outputting a clock signal delayed for a predetermined time; and a plurality of delayed clock selectors corresponding to the plurality of analog signals, for outputting one of the delayed clock signals as the sampling clock signal in response to a received phase control signal.

In another aspect of the present invention, there is provided a flat panel display for receiving a synchronization signal and a plurality of analog image signals provided from a host and displaying an image, the device including: a display panel; analog-to-digital converters corresponding to the plurality of analog image signals, for converting the received analog image signals into a digital signal in response to corresponding sampling clock signals and providing the display panel with the converted digital signal; and a clock generator for receiving the synchronization signal and generating the sampling clock signals, wherein the clock generator generates the sampling clock signals for the analog-to-digital converters to convert the received analog signal into a digital signal when each of the analog signals inputted to each of the analog-to-digital converters is in stable regions.

In one embodiment, the clock generator includes: a pixel clock generator for dividing a frequency of the synchronization signal and generating a pixel clock signal.

In this embodiment, the clock generator can include: clock delay circuits corresponding to the plurality of analog signals, for delaying the pixel clock signal for a predetermined time and generating a sampling clock signal.

In one embodiment, the clock generator generates the sampling clock signals in response to phase control signals corresponding to the analog signals.

In this embodiment, the clock delay circuit can delay the synchronization signal for a predetermined time corresponding to a received phase control signal and generates a sampling clock signal.

In this embodiment, the clock delay circuit can include: a plurality of delayers connected in series, for receiving the synchronization signal; and a clock selector for outputting an output of a delayer corresponding to the received phase control signal among the delayers as the sampling clock signal.

In one embodiment, the clock generator includes: a plurality of delayers connected in series, for receiving the clock signal and outputting a clock signal delayed for a predetermined time; and a plurality of delayed clock selectors corresponding to the plurality of analog signals, for outputting one of the delayed clock signals as the sampling clock signal in response to a received phase control signal.

In one embodiment, the clock generator further includes: an output clock selector for supplying the display panel with one of the sampling clock signals outputted from the clock delay circuits as an output clock signal.

In this embodiment, the display panel can display an N-channel digital signal outputted from the analog-to-digital converters synchronized with the output clock signal outputted from the clock generator.

In one embodiment, the N-channel analog image signal includes R-, G- and B-analog image signals.

The term “channel” used in this specification implies a path through which an analog signal travels. In detail, each of R-, G- and B-analog signals is referred to as a channel.

### BRIEF DESCRIPTION OF THE DRAWINGS

The foregoing and other objects, features and advantages of the invention will be apparent from the more particular description of a preferred embodiment of the invention, as illustrated in the accompanying drawings in which like reference characters refer to the same parts throughout the different views. The drawings are not necessarily to scale, emphasis instead being placed upon illustrating the principles of the invention.

FIG. 1 illustrates an example of an analog signal received by a display device, which is transmitted from a computer graphic interface through a cable.

FIG. 2 illustrates an example of image signals sampled with a same sampling clock signal.

FIG. 3 is a block diagram of an analog-to-digital conversion device according to an embodiment of the present invention.

FIG. 4 illustrates a flat panel display provided with an analog-to-digital converter according to an embodiment of the present invention.

FIG. 5 is a block diagram illustrating a sampling clock generator of FIG. 4.

FIG. 6 illustrates a detailed configuration of the clock delay circuit of FIG. 5.

FIG. 7 is a block diagram illustrating a sampling clock generator of FIG. 4.

FIG. 8 illustrates digital image signals, sampling clock signals and an output clock signal outputted from the analog-to-digital converters of FIG. 4.

FIG. 9 illustrates sampling points of an analog image signal in analog-to-digital converters of FIG. 4.

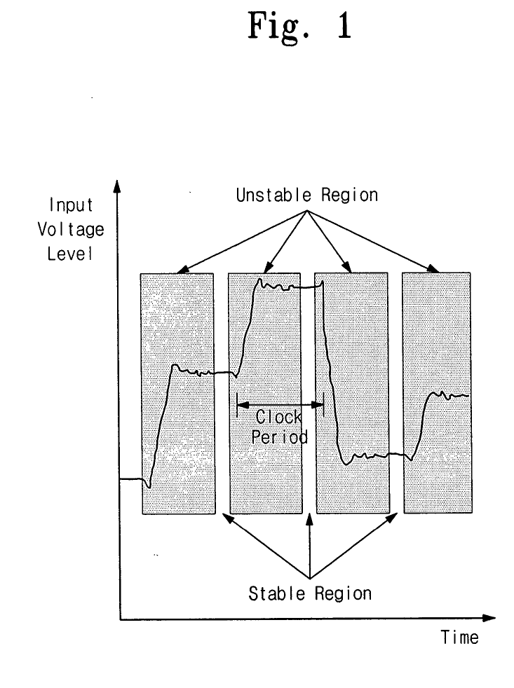

### DETAILED DESCRIPTION OF THE INVENTION

FIG. 3 is a block diagram of an analog-to-digital conversion device according to an embodiment of the present invention. Referring to FIG. 3, an analog-to-digital conversion apparatus 10 includes a sampling clock generator 11 and an analog-to-digital converter 12. The sampling clock generator 11 receives a clock signal CLK and generates a plurality of sampling clock signals S in response to phase control signals PH. The analog-to-digital converter 12 receives a plurality of analog signals A, samples each of the received analog signals and outputs digital signals D synchronized with the sampling clock signals S outputted from the sampling clock generator 11. Each of the sampling clock signals S outputted from the sampling clock generator 11 corresponds to each of the analog signals A. Therefore, the analog-to-digital converter 12 can output the optimal digital signals D.

In general, display devices use R-, G- and B-color filters corresponding to the three primary colors of light. The display device receives color signals corresponding to color filters and controls the brightness of the filter to represent various colors. In this specification, the invention is described in the context of a display device employing the converter of the invention for converting the R-, G- and B-analog image signals into digital signals. However, the plurality of analog signals to which the invention is directed is not limited to R-, G- and B-analog image signals. The analog-to-digital converter of the invention can be applied to various electronic devices as well as a display device and used independently.

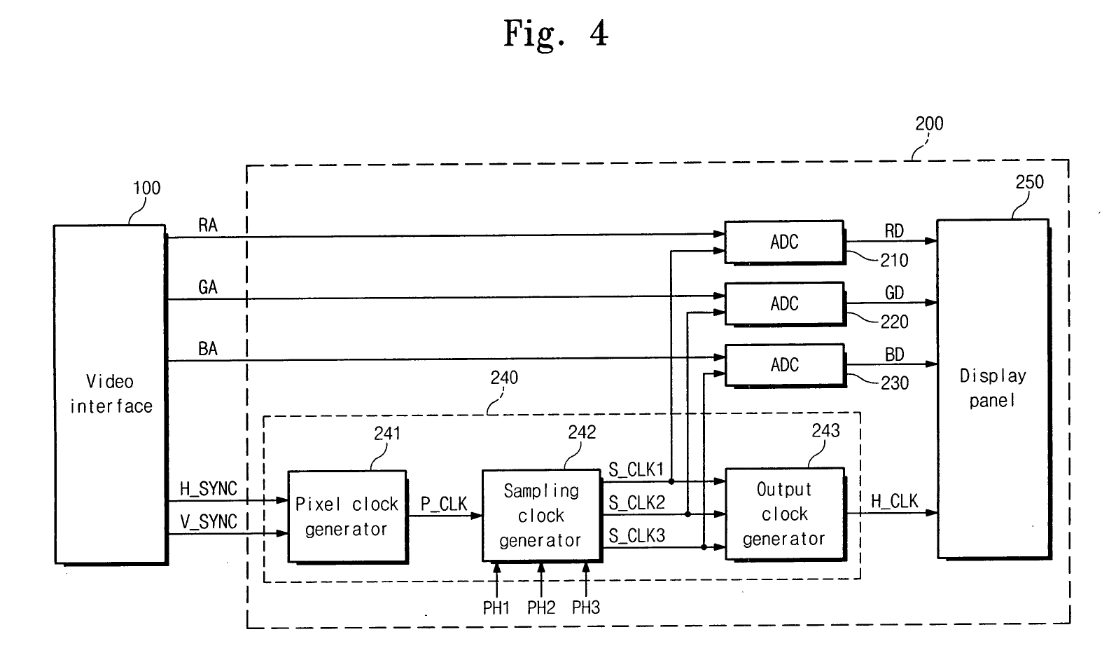

FIG. 4 illustrates a flat panel display provided with an analog-to-digital converter according to an embodiment of the present invention. Referring to FIG. 4, the flat panel display 200 of the present invention receives analog image signals RA, GA and BA and synchronization signals H_SYNC and V_SYNC from a video interface 100 to display an image. The flat panel display 200 includes analog-to-digital converters 210, 220 and 230 corresponding respectively to the plurality of analog image signals, a clock generator 240 and a display panel 250. The analog-to-digital converters 210, 220 and 230 convert the received analog image signals into digital signals in response to corresponding sampling clock signals and provide the display panel 250 with the converted digital signals.

The clock generator 240 includes a pixel clock generator 241, a sampling clock generator 242 and an output clock selector 243. The pixel clock generator 241 receives horizontal and vertical synchronization signals H_SYNC and V_SYNC provided from a video interface 100, divides a frequency of the horizontal synchronization signal H_SYNC and generates a pixel clock signal P_CLK. The pixel clock generator 241 includes a clock recovery circuit such as a phase locked loop (PLL). The frequency of the pixel clock signal P_CLK is the same as the frequency of the analog image signals RA, GA and BA.

The sampling clock generator 242 receives the pixel clock signal P_CLK from the pixel clock generator 241 and generates sampling clock signals S_CLK1, S_CLK2 and S_CLK3 to be provided to the analog-to-digital converters 210, 220 and 230 in response to the phase control signals PH1, PH2 and PH3. The phase control signals PH1, PH2 and PH3 are provided to a controller (not shown) of the display 200 or the video interface 100. The display 200 includes an on-screen display (OSD) controller (not shown) and a plurality of OSD control buttons. A user can control image brightness, contrast, horizontal position, vertical position, phase and frequency. Therefore, the display 200 can be configured so that the phases of the sampling clock signals can be controlled by manipulating the OSD control buttons. Here, the phase control signals PH1, PH2 and PH3 are the signals for controlling the phases of the sampling clock signals by manipulating OSD control buttons. The method for generating the phase control signals PH1, PH2 and PH3 can be modified in various ways, in addition to the OSD manner.

The output clock selector 243 selects one of the sampling clock signals S-CLK1, S_CLK2 and S_CLK 3 outputted from the sampling clock generator 242 and outputs the selected signal as an output clock signal H_CLK. The output clock signal H_CLK is supplied to the display panel 250.

The display panel 250 displays digital image signals RD, GD and BD outputted from the analog-to-digital converters synchronized with the output clock signal H_CLK outputted from a selector 243.

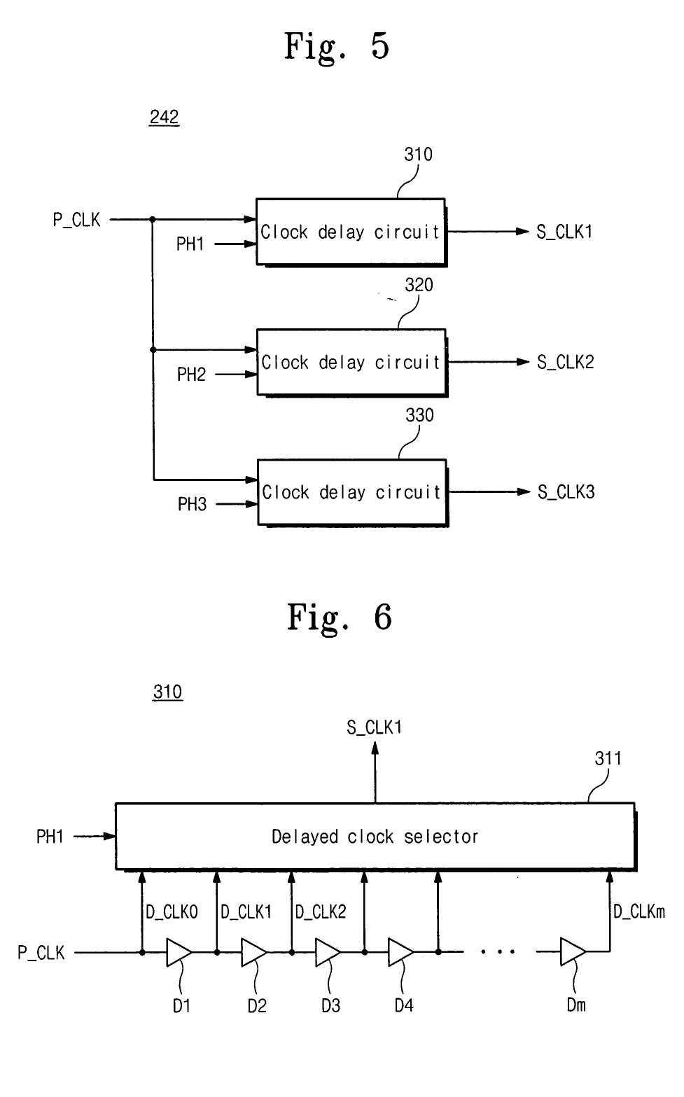

FIG. 5 is a block diagram illustrating a sampling clock generator of FIG. 4. Referring to FIG. 5, the sampling clock generator 242 includes clock delay circuits 310, 320 and 330 corresponding to the analog-to-digital converters 210, 220 and 230. Each of the clock delay circuits 310, 320 and 330 delays the pixel clock signal P_CLK in response to the corresponding phase control signal and outputs the delayed signal as a sampling clock signal.

FIG. 6 illustrates a detailed configuration of the clock delay circuit 310 of FIG. 5. In this specification, even though only the clock delay circuit 310 is illustrated and described, the remaining clock delay circuits 320 and 330 have the same configuration and operate in the same manner as the clock delay circuit 310. Referring to FIG. 5, the clock delay circuit 310 includes a delayed clock selector 311 and delaying elements D1-Dm. The delaying elements D1-Dm are connected in series and the delaying element D1 receives a pixel clock signal.

The delaying elements D1-Dm output delayed signals D_CLK0-D_CLKm that are obtained by delaying the pixel clock signal P_CLK. That is, the phase of the delayed clock signals D_CLK0-D_CLKm are different from the phase of the pixel clock signal P_CLK. The phases of the delayed clock signals D_CLK0-D_CLKm are different from each other. Here, the phase difference between the pixel clock signal P_CLK and the delayed clock signal D_CLKm should be less than one period of the pixel clock signal P_CLK. The signal D_CLK0 has the same phase as the pixel clock signal P_CLK. The delay clock selector 311 outputs one of the signals D_CLK1-D_CLKm as a sampling clock signal S_CLK1 in response to the phase control signal PH1. The sampling clock signal S_CLK1 is supplied to the analog-to-digital converter 210.

As described above, since the phases of the sampling clock signals S_CLK1, S_CLK2 and S_CLK3 are selected according to the phase control signals PH1, PH2 and PH3, the sampling time of the analog-to-digital converters 210, 220 and 230 can be set to be different from each other. Thus, the analog-to-digital converters 210, 220 and 230 can sample the inputted analog image signals RA, GA and BA when the inputted analog image signals RA, GA and BA are in a stable state or region.

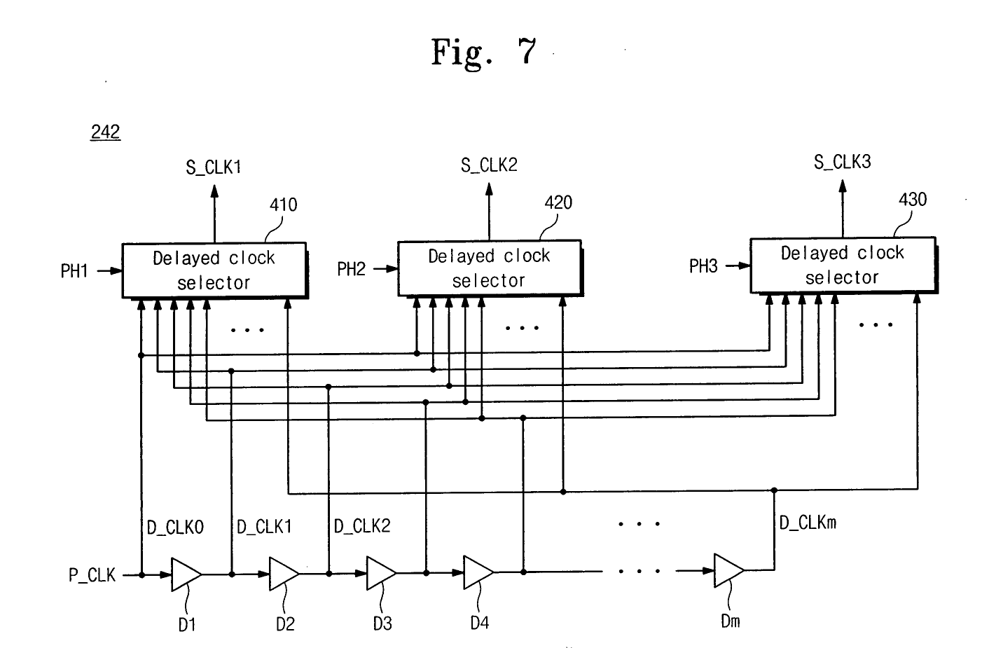

FIG. 7 is a block diagram illustrating a sampling clock generator 242 of FIG. 4.

Referring to FIG. 7, the sampling clock generator 242 includes a plurality of delayed clock selectors 410, 420 and 430 corresponding to the plurality of analog signals and a plurality of delayers or delay units D1-Dm. The plurality of delayers D1-Dm are sequentially connected in series and receive the pixel clock signal. The delayers D1-Dm output clock signals D_CLK1-D_CLKm obtained by delaying the pixel clock signal P_CLK. That is, the phases of the delayed clock signals D_CLK1-D_CLKm are different from that of the pixel clock signal P_CLK and the phases of the delayed clock signals D_CLK1-D_CLKm are also different from each other. Here, the phase difference between the pixel clock signal P_CLK and the delayed clock signal D_CLKm should be less than a period of the pixel clock signal P_CLK. The phase of the signal D_CLK0 is the same as that of the pixel clock signal P_CLK.

According to the present invention, the analog-to-digital converters 210, 220 and 230 can sample the inputted analog image signals RA, GA and BA when the inputted analog image signals RA, GA and BA are in the stable state. Therefore, quality of the image displayed on a display panel 250 is improved.

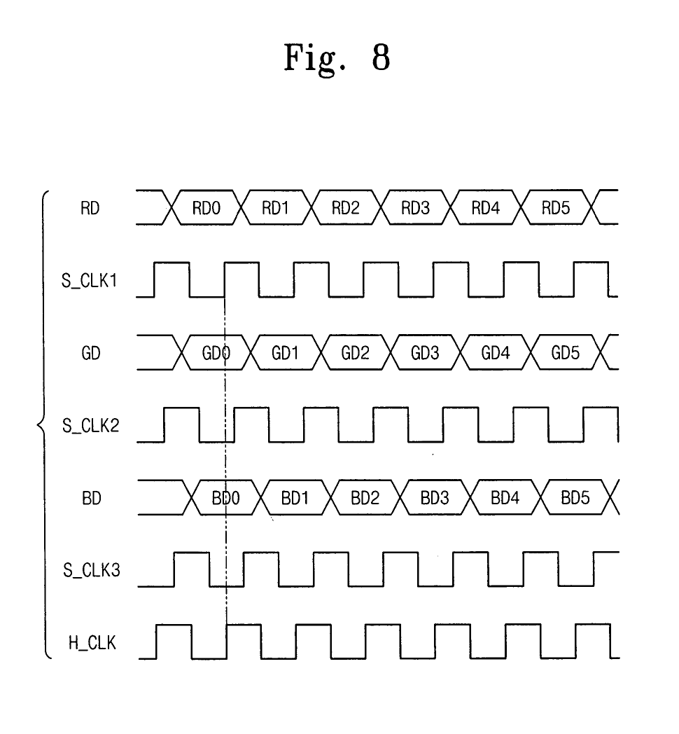

FIG. 8 illustrates digital image signals RD, GA and BA, sampling clock signals S_CLK₁, S_CLK2 and S_CLK3 and an output clock signal H_CLK outputted from the analog-to-digital converters 210, 220 and 230 of FIG. 4. The sampling clock signal whose phase leads those of all the other sampling clock signals among the sampling clock signals S_CLK1, S_CLK2 and S_CLK3 outputted from the sampling clock generator 242 is outputted as the output clock signal H_CLK.

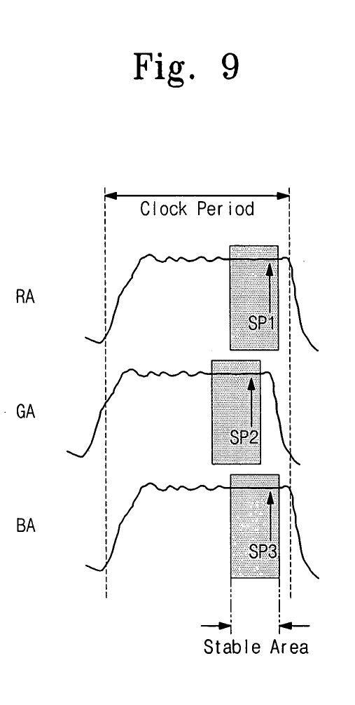

FIG. 9 illustrates sampling points of an analog image signal in analog-to-digital converters of FIG. 4. The points SP1, SP2 and SP3 at which the analog-to-digital converters 210, 220 and 230 sample the analog image signals RA, GA and BA are different from each other. Since the sampling points for the analog image signals RA, GA and BA are variable, the analog-to-digital converter 210, 220 and 230 can sample the analog image signals RA, GA and BA when analog image signals RA, GA and BA are in the stable state.

As shown in FIG. 9, it is found that when a plurality of analog signals which are not synchronized with each other or whose stable regions do not coincide with each other are sampled by the sampling clock signals whose phases are the same as each other, the region in which the plurality of analog signals are sampled in the stable regions is the same as the stable region of each of analog signals.

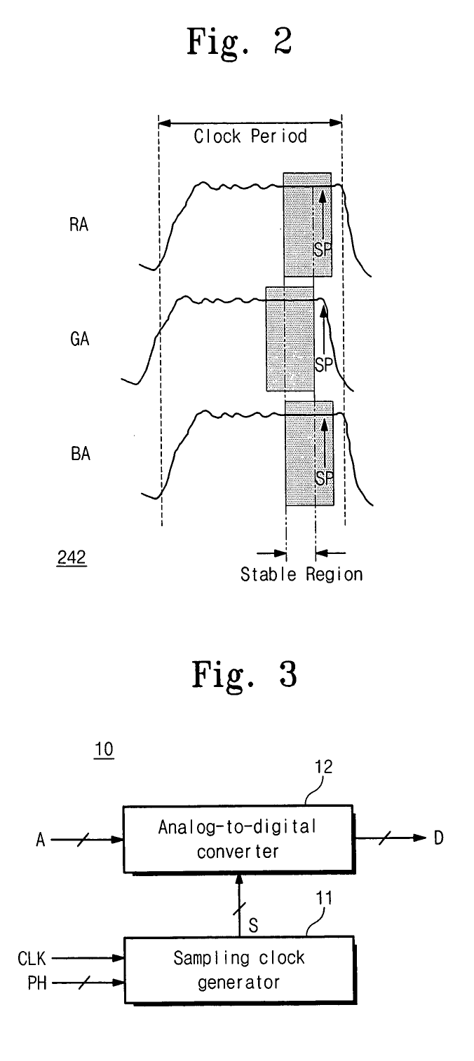

Accordingly, as shown FIGS. 2 and 9, to illustrate the invention, it is assumed for illustration that a plurality of analog signals which are not synchronized with each other or whose stable regions do not coincide with each other are inputted. Then, the more precise data can be obtained if the plurality of analog signals are sampled by the sampling clock signals used to sample the analog signals respectively rather than the case of the plurality of analog signals being sampled by the sampling clock signals whose phases are the same as each other.

According to the present invention, the analog-to-digital conversion apparatus can change the sampling points of the plurality of analog signals. Thus, the analog-to-digital conversion apparatus can convert the plurality of analog signals into digital signals when the plurality of analog signals are in the stable state.

Although the present invention is described using exemplary preferred embodiments, the scope of the present invention is not limited to the preferred embodiments. It will be apparent to those skilled in the art that various modifications and variations can be made in the present invention. Thus, it is intended that the present invention covers the modifications and variations of this invention provided they come within the scope of the appended claims and their equivalents.

1. A sampling apparatus comprising:
a clock generator for receiving a clock signal and generating sampling clock signals; and
a sampling circuit for receiving a plurality of analog signals and sampling the received analog signals synchronized with the sampling clock signals,
wherein the clock generator generates the sampling clock signals to change sampling points for the plurality of analog signals.

2. The apparatus of claim 1, wherein each of the analog signals corresponds to each of the sampling clock signals in a one-to-one manner.

3. The apparatus of claim 2, wherein the sampling circuit comprises a plurality of sampling units each corresponding to each of the plurality of analog signals, for sampling the corresponding analog signal synchronized with the corresponding sampling clock signal.

4. The apparatus of claim 2, wherein the clock generator generates the sampling clock signals in response to phase control signals each corresponding to each of the analog signals.

5. An analog-to-digital conversion apparatus comprising:
a clock generator for receiving a clock signal and generating sampling clock signals; and
an analog-to-digital converter for receiving a plurality of analog signals and converting the received analog signals into digital signals synchronized with the sampling clock signals,
wherein the clock generator generates the sampling clock signals for the analog-to-digital converter to change sampling points for the plurality of analog signals.

6. The apparatus of claim 5, wherein the clock generator generates the sampling clock signals for the analog-to-digital converter to convert the analog signals into the digital signals when all the plurality of analog signals are in a stable state.

7. The apparatus of claim 5, wherein the analog-to-digital converter comprises a plurality of conversion units each corresponding to each of the plurality of analog signals, for converting the corresponding analog signal into a digital signal synchronized with the corresponding sampling clock signal.

8. The apparatus of claim 7, wherein the clock generator generates the sampling clock signals in response to phase control signals corresponding to the analog signals.

9. The apparatus of claim 8, wherein the clock generator comprises clock delay circuits corresponding to the analog signals, for delaying the clock signal for a predetermined time and generating the sampling clock signal.

10. The apparatus of claim 8, wherein each of the clock delay circuits delays the clock signal for a time corresponding to the received phase control signal and generates the sampling clock signal.

11. The apparatus of claim 10, wherein each of the clock delay circuits comprises:
a plurality of delayers connected in series, for receiving the synchronization signal; and
a clock selector for outputting an output of a delayer corresponding to the received phase control signal among the delayers as a sampling clock signal.

12. The apparatus of claim 5, wherein the clock generator comprises:
a plurality of delayers connected in series, for receiving the clock signal and outputting a clock signal delayed for a predetermined time; and
a plurality of delayed clock selectors corresponding to the plurality of analog signals, for outputting one of the delayed clock signals as the sampling clock signal in response to a received phase control signal.

13. A flat panel display for receiving a synchronization signal and a plurality of analog image signals provided from a host and displaying an image, the device comprising:
a display panel;
analog-to-digital converters corresponding to the plurality of analog image signals, for converting the received analog image signals into digital signals in response to corresponding sampling clock signals and providing the display panel with the converted digital signals; and
a clock generator for receiving the synchronization signal and generating the sampling clock signals,
wherein the clock generator generates the sampling clock signals for the analog-to-digital converters to convert the received analog signal into a digital signal when each of the analog signals inputted to each of the analog-to-digital converters is in a stable state.

14. The device of claim 13, wherein the clock generator comprises: a pixel clock generator for dividing a frequency of the synchronization signal and generating a pixel clock signal.

15. The device of claim 14, wherein the clock generator comprises: clock delay circuits corresponding to the plurality of analog signals, for delaying the pixel clock signal for a predetermined time and generating a sampling clock signal.

16. The device of claim 14, wherein the clock generator generates the sampling clock signals in response to phase control signals corresponding to the analog signals.

17. The device of claim 16, wherein the clock delay circuit delays the synchronization signal for a predetermined time corresponding to a received phase control signal and generates a sampling clock signal.

18. The device of claim 17, wherein the clock delay circuit comprises:
a plurality of delayers connected in series, for receiving the synchronization signal; and
a clock selector for outputting an output of a delayer corresponding to the received phase control signal among the delayers as the sampling clock signal.

19. The device of claim 15, wherein the clock generator comprises:
a plurality of delayers connected in series, for receiving the clock signal and outputting a clock signal delayed for a predetermined time; and
a plurality of delayed clock selectors corresponding to the plurality of analog signals, for outputting one of the delayed clock signals as the sampling clock signal in response to a received phase control signal.

20. The device of claim 14, wherein the clock generator further comprises: an output clock selector for supplying the display panel with one of the sampling clock signals outputted from the clock delay circuits as an output clock signal.

21. The device of claim 20, wherein the display panel displays an N-channel digital signal outputted from the analog-to-digital converters synchronized with the output clock signal outputted from the clock generator.

22. The device of claim 13, wherein the N-channel analog image signal comprises R (red)-, G (green)- and B (blue)-analog image signals.
